(19) United States
(12) Patent Application Publication
(10) Pub. No.: US 2025/0169166 A1
(43) Pub. Date: May 22, 2025

(54) ENHANCED ISOLATION FOR ON-CHIP CURRENT SENSORS

(71) Applicant: Wolfspeed, Inc., Durham, NC (US)

(72) Inventors: Madankumar Sampath, Morrisville, NC (US); Sei-Hyung Ryu, Cary, NC (US)

(21) Appl. No.: 18/510,756

(22) Filed: Nov. 16, 2023

(51) Int. Cl. H01L 27/088; G01R 19/00

(52) U.S. Cl. CPC H10D 84/83; G01R 19/0046

(57) ABSTRACT

A semiconductor device includes a device active region comprising a first well, at least a portion of the first well being part of a first metal-oxide-semiconductor field-effect transistor (MOSFET), and a sensor region comprising a second well, at least a portion of the second well being part of a second MOSFET configured to mirror a current in the first MOSFET. A distance between an outer edge of the second well and an inner edge of the first well is constant or the distance decreases approaching one or more vertices of the second well.

### FIELD

The present disclosure relates generally to semiconductor devices, and, more particularly, to semiconductor devices with on-chip current sensors that are at least partly on the same die as the semiconductor device.

### BACKGROUND

Semiconductor devices are ubiquitous in modern electronic devices. Wide bandgap semiconductor material systems, such as gallium nitride (GaN) and silicon carbide (SiC), are increasingly utilized in semiconductor devices to push the boundaries of device performance in areas such as switching speed, power handling capability, and heat dissipation. Examples include individual devices such as metal-oxide-semiconductor field-effect transistors (MOSFETs), insulated gate bipolar transistors (IGBTs), Schottky barrier diodes, PIN diodes, high electron mobility transistors (HEMTs), and integrated circuits such as monolithic microwave integrated circuits (MMICs) that include one or more individual devices.

Current sensing in semiconductor devices for power switching and other applications is one way to monitor operating load currents in the devices to detect possible failure mechanisms like overcurrent or short-circuit events. In the example of a MOSFET, current sensing may be accomplished by integrating a current sensor at least partly on the same die as the MOSFET (herein a semiconductor device that has a current sensor that is at least partly integrated on the same die is referred to as having an “on-chip” current sensor). However, while various current sensing arrangements in semiconductor devices have been proposed, conventional structures may not be suitable for withstanding various adverse operating conditions that may be experienced.

### SUMMARY

The present invention, as manifested in the embodiments disclosed herein, is directed to semiconductor devices. A semiconductor device may include a device active region that implements the intended functionality of the semiconductor device and a sensor active region, for example, a current sensor active region that senses a parameter (e.g., current) of the device active region. For example, a current sensor active region may be configured to mirror (i.e., replicate) a load current in the device active region during operation of the semiconductor device for purposes of measuring the load current in the device active region. In example embodiments, the semiconductor device may comprise a MOSFET with an on-chip current sensor and may include at least one device MOSFET in the device active region and at least one sensing MOSFET in the sensor active region, where the sensing MOSFET is configured to mirror the current in the device MOSFET. The device MOSFET may include a first well under a source pad of the semiconductor device, and the sensing MOSFET may include a second well under a sense pad of the semiconductor device. An isolation structure may be positioned in between the first and second wells. In some embodiments, the isolation structure may comprise an isolation region that includes a high-resistance electrical connection between the first and second wells. The high-resistance electrical connection is configured to provide sufficient isolation between the device MOSFET and the sensing MOSFET to prevent current in the device active region from propagating into the sensor active region, so that fluctuations in threshold voltage between the device MOSFET and sensing MOSFET are eliminated or reduced, without affecting breakdown voltage in the semiconductor device. In other embodiments, the isolation structure may comprise an isolation region that electrically disconnects the first and second wells, where the distance between the first and second wells is constant about the periphery of the second well, or decreases approaching one or more vertices of the second well. Such a design may advantageously increase the breakdown voltage of the semiconductor device having the on-chip current sensor. Isolation structures that employ both of the above-described approaches may also be provided.

In accordance with an embodiment of the present disclosure, a semiconductor device includes a device active region and a sensor region. The device active region includes a first well, at least a portion of the first well being part of a first MOSFET. The sensor region includes a second well, at least a portion of the second well being part of a second MOSFET configured to mirror a current in the first MOSFET. A distance between an outer edge of the second well and an inner edge of the first well is constant or the distance decreases approaching one or more vertices of the second well.

In accordance with another embodiment, a semiconductor device comprises a device active region comprising a first well and a sensor active region comprising a second well. At least a portion of the first well is part of a first MOSFET, and at least a portion of the second well is part of a second MOSFET that is configured to mirror a current in the first MOSFET. When viewed in plan view, the first well surrounds the second well, and a distance between an outer edge of the second well and an inner edge of the first well at corners of the second well is less than or equal to the distance between the outer edge of the second well and the inner edge of the first well at sides of the second well.

In accordance with another embodiment, a semiconductor device comprises a semiconductor layer structure that comprises a device active region including a first well having a second conductivity type, and a sensor active region including a second well having the second conductivity type. At least a portion of the first well is part of a first MOSFET, and at least a portion of the second well is part of a second MOSFET that is configured to mirror a current in the first MOSFET. The semiconductor device further comprises an isolation structure comprising a first region that electrically isolates the first well from the second well and a second region that electrically connects to the first well to the second well.

In accordance with another embodiment, a method of forming a semiconductor device comprising an on-chip current mirror comprises: providing a device active region comprising a first well, at least a portion of the first well being part of a first MOSFET; providing a sensor active region comprising a second well, at least a portion of the second well being part of a second MOSFET configured to mirror a current in the first MOSFET; and providing an isolation structure between the first and second wells. A distance between outer edges of the second well and inner edges of the first well is constant or the distance decreases approaching one or more vertices of the second well.

In accordance with another embodiment, a method of forming a semiconductor device comprising an on-chip current mirror comprises: providing a device active region comprising a first well, the first well being part of a first MOSFET; and providing a sensor active region comprising a second well, the second well being part of a second MOSFET that is configured to mirror (i.e., replicate) a current in the first MOSFET. The second well is laterally separated from the first well, a distance between an outer edge of the second well and an inner edge of the first well at corners of the second well being less than or equal to the distance between the outer edge of the second well and the inner edge of the first well at sides of the second well.

In accordance with another embodiment, a semiconductor device comprises a device active region, a sensor region, and an isolation structure in between the device active region and the sensor region. The isolation structure has an inner perimeter and an outer perimeter when viewed in plan view and the inner perimeter is not conformal to the outer perimeter, at least one of the inner perimeter and the outer perimeter includes at least one curve, a spacing between the inner and outer perimeters is constant, and/or a high resistance electrical connection is provided between the device active region and the sensor active region.

Aspects of the present inventive concept can provide substantial beneficial technical effects. By way of example only and without limitation, techniques according to embodiments of the present disclosure may provide one or more of the following advantages, among other benefits:
prevents current in a device active region from propagating into a sensor active region of a semiconductor device, so that fluctuations in threshold voltage between a sensing MOSFET and a device MOSFET being sensed are eliminated or reduced;
provides isolation between the device MOSFET and sensing MOSFET without significantly affecting breakdown voltage in the device MOSFET;
easily integrates with existing fabrication processes without requiring additional masks or increasing device fabrication complexity.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 illustrates a top view layout for an example semiconductor device in which embodiments of the present disclosure may be implemented;

FIG. 2A is a schematic diagram depicting a first equivalent circuit for an implementation of a MOSFET having a current sensor in which embodiments of the present disclosure may be utilized;

FIG. 2B is a schematic diagram depicting a second equivalent circuit for an implementation of a MOSFET having a current sensor in which embodiments of the present disclosure may be utilized;

FIG. 3 is a top view layout of at least a portion of an example semiconductor device including an on-chip current sensor integrated with a device MOSFET being monitored, in which embodiments of the present disclosure may be implemented;

FIGS. 4A and 4B are schematic top (plan) views depicting a portion of the example semiconductor device shown in FIG. 3, showing two different known interfaces between the sensing MOSFET and the device MOSFET being monitored;

FIGS. 5A-5E are schematic top (plan) views of a portion of an illustrative semiconductor device (e.g., semiconductor device shown in FIG. 3), conceptually depicting several different approaches for isolating the sensing MOSFET from the device MOSFET being sensed, while retaining breakdown voltage performance characteristics of the semiconductor device, according to embodiments of the present disclosure.

FIGS. 6A-6B are schematic top (plan) views of a portion of an illustrative semiconductor device (e.g., semiconductor device shown in FIG. 3), conceptually depicting additional approaches for isolating the sensing MOSFET from the device MOSFET being sensed, while retaining breakdown voltage performance characteristics of the semiconductor device, according to embodiments of the present disclosure.

FIG. 7 is a schematic top view of a portion of an illustrative semiconductor device (e.g., semiconductor device shown in FIG. 3), conceptually depicting an additional approach for isolating the sensing MOSFET from the device MOSFET being sensed, while retaining breakdown voltage performance characteristics of the semiconductor device, according to embodiments of the present disclosure.

FIGS. 8A-8C are schematic cross-sectional views of MOSFET devices according to embodiments of the present disclosure.

In the top views described above, various layers such as upper metal and insulating layers are omitted to illustrate other regions of the devices.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in the embodiments disclosed herein, are described in the context of semiconductor devices including at least one power MOSFET integrated with at least one on-chip current sensor, and more specifically to embodiments of a semiconductor device having enhanced isolation between an on-chip current sensor and a power MOSFET, which may be suitable for use in a power switching environment, among other beneficial applications. It is to be appreciated, however, that the invention is not limited to the specific devices, circuits, systems and/or methods illustratively shown and described herein. Rather, it will become apparent to those skilled in the art given the teachings herein that numerous modifications to the embodiments shown are contemplated and are within the scope of the present inventive concept. That is, no limitations with respect to the embodiments shown and described herein are intended or should be inferred.

It will be understood that, although the ordinal terms first, second, etc., may be used herein to describe various elements, these elements should not be limited by such terms. These terms are only used to distinguish one element from another. For example, a first element could be termed a second element and similarly, a second element could be termed a first element, without departing from the scope of the present disclosure. As used herein, the term “and/or” includes any and all combinations of one or more of the associated listed items.

For the purpose of describing and claiming embodiments of the present disclosure, the term MISFET as may be used herein is intended to be construed broadly and to encompass any type of metal-insulator-semiconductor field-effect transistor. The term MISFET is, for example, intended to encompass semiconductor field-effect transistors that utilize an oxide material as their gate dielectric (i.e., MOSFETs), as well as those that do not. In addition, despite a reference to the term “metal” in the acronyms MISFET and MOSFET, the terms MISFET and MOSFET are also intended to encompass semiconductor field-effect transistors wherein the gate is formed from a non-metal material such as, for instance, polysilicon; the terms “MISFET” and “MOSFET” may be used interchangeably herein.

Although the overall fabrication method and structures formed thereby as described herein are entirely novel, certain individual processing steps required to implement a portion or portions of the method(s) according to one or more embodiments of the inventive concept may utilize conventional semiconductor fabrication techniques and/or conventional semiconductor fabrication tooling. These techniques and tooling will already be familiar to one having ordinary skill in the relevant art. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are incorporated by reference herein in their entireties. It is emphasized that while some individual processing steps are set forth herein, those steps are merely illustrative and one skilled in the art may be familiar with several equally suitable alternatives that would also fall within the scope of the present disclosure.

It will be understood that when an element such as a layer, region, or structure is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or structure is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below,” “above,” “upper,” “lower,” “top,” “bottom,” “under,” “over,” “horizontal,” “vertical,” etc., as may be used herein, are intended to describe a spatial relationship of one element, layer, or region to another element, layer, or region as illustrated in the figures, rather than an absolute position of the element, layer, or region. It will be understood that these terms and those discussed above are intended to encompass different orientations of the device in addition to the orientation depicted in the figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

The term “surround” (or “surrounding,” “surrounds,” or other like terms) as used herein is intended to refer to an element, such as a component, structure, layer or region, that envelops, encircles, encloses, or extends around another element on all sides when the device is viewed in plan view, although breaks or gaps may also be present. Thus, for example, a material layer having voids or openings therein may still “surround” another layer which it encircles. The term “completely surrounds” may be used if no breaks of gaps are present.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

A power MOSFET typically includes a large number of unit cells. Each unit cell may comprise an individual MOSFET, and the unit cells are electrically connected together in parallel with one another; that is, with their gates connected together, their drains connected together, and their sources connected together. In order to facilitate the sensing of a load current associated with the power MOSFET when it is conducting or switched on, without requiring a series resistor to pass all of the load current (resulting in significant and undesired power dissipation), it is known to provide a current sensing MOSFET in which one or a relatively small number of the MOSFET cells are connected to the power MOSFET in a current mirror configuration. As is well known in the art, a current mirror is a circuit which functions to generate a copy of a current flowing into or out of an input terminal of the circuit (i.e., a reference current) by replicating the current in an output terminal of the circuit irrespective of the load conditions. The replicated output current may be equal to the input current or it may be scaled by a prescribed factor or ratio.

The current sensing MOSFET typically includes a separate source terminal, referred to as a sense pad or terminal. The current sensing MOSFET also typically comprises a plurality of unit cells that each comprise an individual MOSFET, where the unit cells are electrically connected together in parallel, although in some cases the current sensing MOSFET may be implemented as a single unit cell. An external current sensing resistor can be connected between the sense pad and ground (or another voltage source), and may be on the semiconductor die or implemented off the semiconductor die. Since only a predetermined small fraction of the total load current of the power MOSFET passes through the resistor, power dissipation in the current sensing resistor is relatively small.

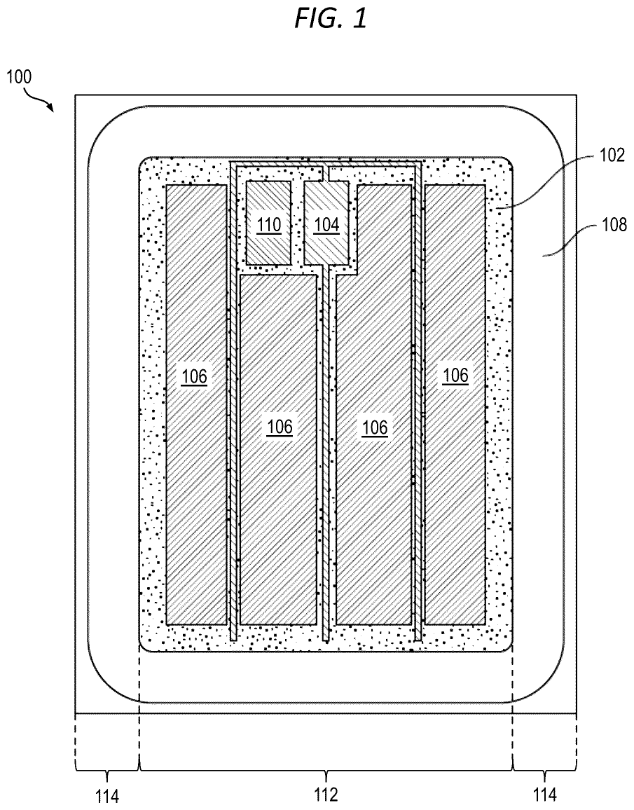

FIG. 1 illustrates a top view layout of an example semiconductor device 100 including an on-chip current sensor. By way of illustration only, the semiconductor device 100 is a vertical MOSFET device comprising a passivation structure 102 formed with openings for a gate contact 104 and one or more source contacts 106. While a MOSFET device is illustrated, the principles of the present disclosure may be applicable to other semiconductor devices as well, for example, other MOSFETs, MISFETs, diodes, Schottky diodes, junction barrier Schottky (JBS) diodes, PIN diodes, and insulated gate bipolar transistors (IGBTs), among others. Thus, while the semiconductor device 100 is illustrated and described herein as being a MOSFET, it will be appreciated that in other embodiments it may be any other applicable semiconductor device, such as the example semiconductor devices listed above. The semiconductor device 100 may embody wide bandgap semiconductor devices, for example, silicon carbide (SiC)-based devices, and still further 4H-SiC based devices.

The MOSFET 100 of FIG. 1 is a vertical power MOSFET in which a drain contact (not explicitly shown) is located on a back side of the semiconductor die, while the gate contact 104 and the source contacts 106 are on the front side of the semiconductor die. The drain contact, the gate contact 104 and the source contacts 106 may be provided as surfaces for coupling the power MOSFET 100 to external circuitry.

An edge termination region 108 may be arranged along a perimeter of the power MOSFET 100. The edge termination region 108 may be arranged to reduce a concentration of an electric field at the edges of the power MOSFET 100 in order to improve the performance thereof. For example, the edge termination region 108 may increase a breakdown voltage of the power MOSFET 100 and/or decrease a leakage current of the power MOSFET 100. By way of example, the edge termination region 108 may include one or more guard rings, a junction termination extension (JTE), and combinations thereof.

The power MOSFET 100 may further comprise a sensor contact 110. The sensor contact 110 may provide a contact for any type of sensor that is at least partially incorporated within the power MOSFET 100, for example, a temperature sensor, a strain sensor, or a current sensor. In the case of a current sensor, a current sensor active region 116 that is electrically connected to the sensor contact 110 may occupy an area of the power MOSFET 100 that would otherwise (i.e., if no on-chip current sensor was provided) form part of a device active region 112 for the power MOSFET 100. In the example of FIG. 1, the portion of the power MOSFET 100 underneath the source contacts 106 may comprise the device active region 112 while the portion of the power MOSFET 100 underneath the gate contact 104 and the edge termination region 108 may each be part of an inactive region 114 of the power MOSFET 100. The portion of the power MOSFET 100 underneath the sensor contact 110 may comprise the sensor active region 116 and may also include a region that is part of the inactive region 114, since the sensor contact 110 is typically larger, and often much larger, than the sensor active region 116.

The sensor contact 110 provides a contact pad that may be electrically connected, for example, by a wire bond or other electrical connection, to one or more external circuit elements for sensor monitoring. The sensor contact 110 may be electrically connected to source regions of the unit cells in the sensor active region 116 of the power MOSFET 100. In the case of a current sensor, the sensor contact 110 may also be electrically connected to one or more external circuit elements for monitoring a portion of the load current that flows in the sensor active region 116 of the power MOSFET 100 that is electrically coupled to the sensor contact 110. The current flowing in the sensor active region 116 of the power MOSFET 100 may mirror (at a predetermined ratio) the current flowing in the device active region 112 of the power MOSFET 100 and hence may be used to measure the current flowing in the device active region 112 of the power MOSFET 100.

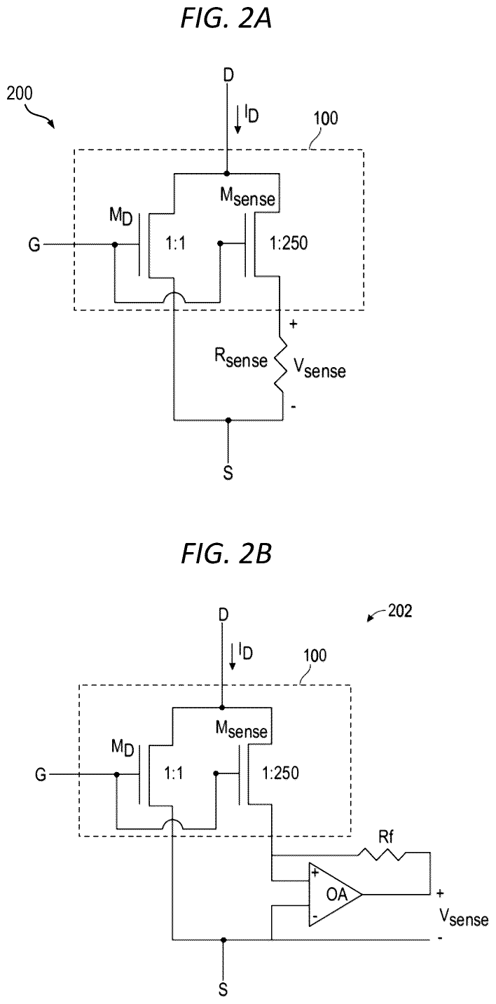

FIG. 2A is a schematic diagram depicting a first equivalent circuit 200 for an implementation of an example current sensor for a MOSFET in which embodiments of the present disclosure may be utilized. A dashed-line box in FIG. 2A represents the power MOSFET 100 of FIG. 1 with the remaining portion of the first equivalent circuit 200 being external to the power MOSFET 100 (i.e., the remaining portion of the first equivalent circuit 200 is “off die”). By forming the sensor contact (e.g., sensor contact 110 of FIG. 1) as a separate source contact, the power MOSFET 100 thereby includes a device MOSFET (M_{D}) and a sensing MOSFET (Mₛₑₙₛₑ) that are connected to a common drain and a common gate. Source connections for each of the MOSFETs (M_{D} and Mₛₑₙₛₑ) are coupled in parallel so that the current flow from the common drain (I_{D}) may be split across the MOSFETs (M_{D} and Mₛₑₙₛₑ). The ratio of current flow from the source of the device MOSFET (M_{D}) to the current flow from the source of the sensing MOSFET (Mₛₑₙₛₑ) corresponds to a ratio of the area of the power MOSFET 100 that is occupied by the device active region 112 to the area of the power MOSFET 100 that is occupied by the sensor active region 116.

By way of example only, FIG. 2A illustrates an embodiment where the ratio of current flow is selected to be 1:250 based on the relative areas of the device MOSFET M_{D} and the sensing MOSFET Mₛₑₙₛₑ. Using this prescribed ratio of current flow, when one amp (A) of current flows through the device active region 112 of power MOSFET 100, four milliamps (mA) of current will flow from the source path of the sensing MOSFET (Mₛₑₙₛₑ), through a sense resistor, Rₛₑₙₛₑ, connected between the source contact of the sensing MOSFET Mₛₑₙₛₑ and a source terminal, S. By arranging the sense resistor Rₛₑₙₛₑ along the source path from the sensing MOSFET Mₛₑₙₛₑ, a corresponding sense voltage, Vₛₑₙₛₑ, may be measured and correlated to the load current of the device MOSFET M_{D}, according to the ratio described above. Other current sensing configurations are possible with the arrangement of the power MOSFET 100.

For example, FIG. 2B is a schematic diagram depicting a second equivalent circuit 202 for an implementation of a current sensor for a MOSFET in which embodiments of the present disclosure may be utilized. The second equivalent circuit 202 shows a virtual ground configuration for the portion that is external to the power MOSFET 100. Virtual ground sensing may be used in applications where a higher value of the sense voltage Vₛₑₙₛₑ is desired. In this configuration, an operational amplifier, OA, and a feedback resistor, Rf, are coupled to the source path from the sensing MOSFET Mₛₑₙₛₑ. In this manner, the sense voltage Vₛₑₙₛₑ may be calculated based on the feedback resistor Rf and an output of the operational amplifier OA.

One benefit of the second equivalent circuit 202, compared with the first equivalent circuit 200 shown in FIG. 2A, is that the virtual ground sensing scheme ensures that the source of the sensing MOSFET Mₛₑₙₛₑ will be the same (or nearly the same) as the source of the device MOSFET M_{D}, thereby providing more accurate current mirroring. In the first equivalent circuit 200 of FIG. 2A, even using a very small sense resistor Rₛₑₙₛₑ, there will always be some finite voltage drop across the sensing resistor which raises the source voltage of the sensing MOSFET, creating a differential in the gate-to-source voltage, V_{gs}, between the device MOSFET M_{D} and sensing MOSFET Mₛₑₙₛₑ. The operational amplifier OA in the second equivalent circuit 202 is configured to force the sources of the device MOSFET M_{D} and the sensing MOSFET Mₛₑₙₛₑ to be the same (or nearly the same) potential.

During operation, the device MOSFET M_{D} may switch from a reverse blocking state (where the device MOSFET M_{D} is not conducting current and may block a very large voltage) to an on-state (where the device MOSFET M_{D} may conduct large currents) in a very short period of time. As the device switches states, a displacement current is generated that flows between a drain terminal on the bottom surface of the semiconductor die and a source terminal on the upper surface of the semiconductor die (in an n-type device).

The displacement current may flow in both the active region and a gate pad portion of the inactive region of the semiconductor layer structure. In each case, a magnitude of the displacement current (I_{Disp}) can be determined as a product of the change in voltage per unit time (dV/dt) across a p-n junction in the semiconductor layer structure of the device MOSFET (which may be, for example, silicon carbide) and a capacitance of this p-n junction (Cₚₙ). In other words:

$${I}_{Disp} = \frac{dV}{dt} \cdot {C}_{pn}$$

In the device active region, there are many paths for the displacement current (since the device MOSFET may be comprised of many unit cells, with each unit cell including a pair of source contacts) and the p-n junctions are small (since a width in the horizontal direction of each p-well that forms a p-n junction with an underlying n-type layer may only be, for example, about 2-3 microns). As such, the capacitance of the p-n junction may be relatively small, reducing the magnitude of the displacement current in the device active region. However, in the gate pad portion of the inactive region, a p-type silicon carbide region that is formed underneath a field insulating layer of the device MOSFET may have a length (in each horizontal direction) of, for example, 100-300 microns, and the displacement current generated in this region must flow to the source contacts of the unit cells closest to the gate pad portion of the inactive region of the semiconductor layer structure. As such, the capacitance of the p-n junction underneath the gate pad portion of the inactive region may be much larger, resulting in a significantly larger displacement current.

In conventional on-chip sensors for monitoring current in a MOSFET device, the large displacement current that can flow in the device MOSFET (M_{D}) can create a leakage current in the sensing MOSFET (Mₛₑₙₛₑ) which may undesirably affect the accuracy of the sensed current. In an effort to eliminate or reduce this leakage current, and thereby improve the accuracy of the sensed current, a first well of the device MOSFET and a second well of the sensing MOSFET may be electrically disconnected from each other, which acts to isolate the sensing MOSFET from the device MOSFET. However, isolating these wells may negatively impact the breakdown voltage of the device MOSFET.

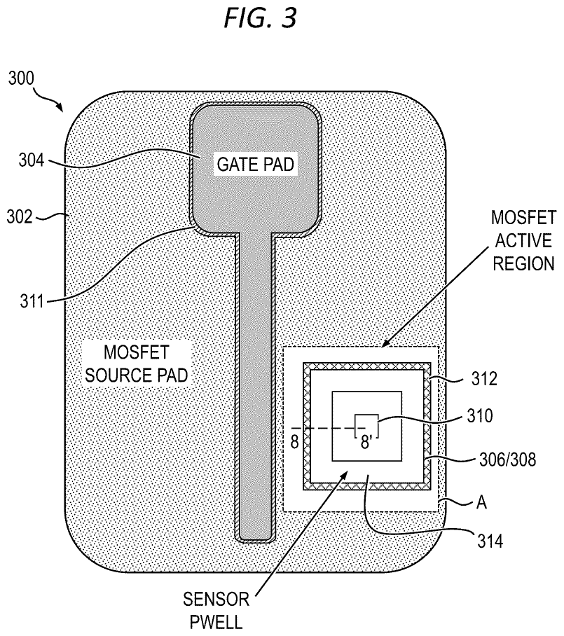

FIG. 3 is a top view layout of at least a portion of an example power MOSFET 300 that includes a device MOSFET and an integrated on-chip current sensor. The power MOSFET 300 includes a MOSFET source pad 302 and a MOSFET gate pad 304 connected to a source and a gate, respectively, of a device MOSFET (e.g., MOSFET M_{D} shown in FIGS. 2A and 2B). The power MOSFET 300 includes a device region 320. The device region 320 may include the source pad 302 of the device MOSFET (e.g., MOSFET M_{D} shown in FIGS. 2A and 2B) and a device active region 322 that is connected to the source pad 302. The power MOSFET 300 may further comprise a sensor region 306 proximate the device MOSFET. The sensor region 306 may include a sense pad 308 of a sensing MOSFET (e.g., MOSFET Mₛₑₙₛₑ shown in FIGS. 2A and 2B) and a sensor active region 310 that is connected to the sense pad 308. The sensor active region 310 includes one or more sensor unit cells that are typically underneath the sense pad 308 and hence are shown using a dashed box in FIG. 3. Typically, the sense pad 308 is larger, and often significantly larger, than the sensor active region 310, as the sense pad 308 may need to be large enough to allow a bond wire to be bonded thereto. Consequently, the sense region 306 may comprise the region below the sense pad 308. The power MOSFET 300 further includes a thin insulating region 311 (e.g., silicon oxide) between the source pad 302 and each of the gate pad 304 and the sense pad 308. The insulating region 311 electrically isolates the pads 302, 304, 308 from each other.

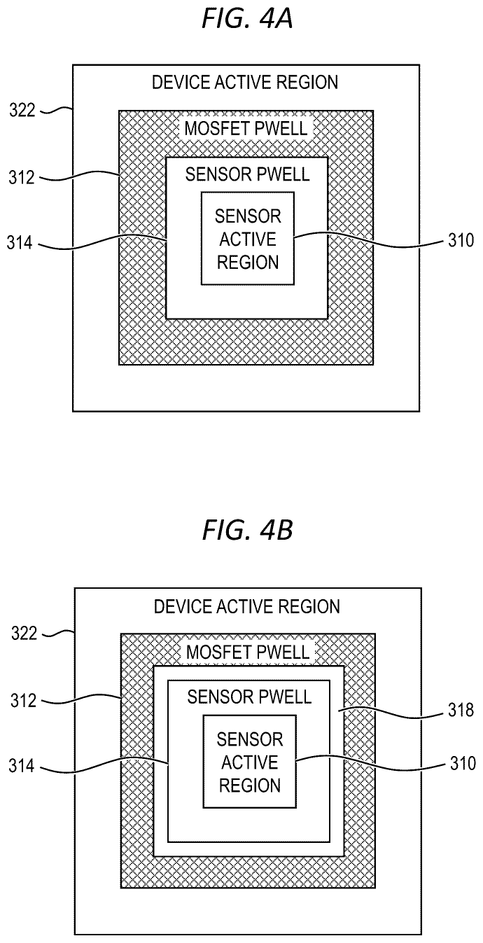

FIG. 4A is a top (plan) view depicting the portion of the example semiconductor device 300 of FIG. 3 that corresponds to the dotted box A in FIG. 3, where FIG. 4A illustrates one known approach for the interface between the device MOSFET and the sensor MOSFET. For clarity purposes, the MOSFET source pad 302 (FIG. 3) and the sense pad 308 (FIG. 3) are omitted in FIG. 4A, as are the source regions, gate electrodes and intermetal dielectric layer(s) so that only the upper surface of the semiconductor layer structure is shown. As an example, the power MOSFET of FIGS. 3 and 4A (and FIGS. 4B, 5A-5E, 6A-6B and 7, discussed below) is assumed to be an n-type power MOSFET so that the active regions of power MOSFET include p-type well regions.

The device MOSFET includes a device active region 322 that includes one or more unit cell transistors. As noted above, the unit cell transistors in the device active region 322 include a first p-well (not separately shown in FIG. 4A) in which channel regions of the unit cell transistors are formed, as is well understood by those of ordinary skill in the art. As shown in FIG. 4A, a portion 312 of the first p-well that is included in the device active region 322 extends from the device active region and may surround the sensor active region 310. This portion 312 of the first p-well may also be referred to herein as the “MOSFET p-well.” Still referring to FIG. 4A, the sensor active region 310 includes one or more unit cell transistors. The unit cell transistors in the sensor active region 310 include a second p-well (not separately shown in FIG. 4A) in which channel regions of the unit cell transistors are formed. As shown in FIG. 4A, a portion 314 of the second p-well extends from and surrounds the sensor active region 310. This portion 314 of the second p-well may also be referred to herein as the “sensor p-well.” The MOSFET p-well 312 may surround the sensor p-well 314. The sensor p-well 314 and the MOSFET p-well 312 may have the same or different doping concentrations. As shown in FIG. 4A, the MOSFET p-well 312 merges into the sensor p-well 314 so that they appear as one large well region and so that the sensor p-well 314 is electrically connected to the MOSFET p-well 312.

It has been discovered that when the sensor p-well 314 is electrically connected to the MOSFET p-well 312 the threshold voltage of the sensing MOSFET may fluctuate in an uncontrolled manner relative to the device MOSFET being sensed, and hence the respective threshold voltages of the sensing MOSFET and device MOSFET may not necessarily track one another. This difference in threshold voltage between the sensing MOSFET and the device MOSFET, which may be due at least in part to a body effect of the device MOSFET, affects the turn-on of the sensing MOSFET. More particularly, the device MOSFET may generate displacement currents that flow through a body region of the device MOSFET. This displacement current through the body region can cause fluctuations in threshold voltage and other parasitic effects which can, in turn, lead to sensing inaccuracies. Thus, if the MOSFET p-well 312 is electrically connected to the sensor p-well 314, then the accuracy of the current sensor may be poor because the displacement current can disrupt operation of the current sensor.

FIG. 4B is a top (plan) view depicting a portion of the example semiconductor device 300 of FIG. 3 that corresponds to the dotted box A in FIG. 3 that illustrates another known approach for the interface between the device MOSFET and the sensor MOSFET. As in FIG. 4A, in FIG. 4B the MOSFET source pad 302 (FIG. 3) and the sense pad 308 (FIG. 3) are omitted, as are the source regions, gate electrodes and intermetal dielectric layer(s) so that only the upper surface of the semiconductor layer structure is shown.

As shown in FIG. 4B, rather than connecting the MOSFET p-well 312 and the sensor p-well 314, the sensor p-well 314 may be electrically disconnected from the MOSFET p-well 312 by interposing a lightly-doped n-type drift region 318 of the semiconductor device 100 in between the MOSFET p-well 312 and the sensor p-well 314. In other embodiments, region 318 may alternatively comprise an insulating material that may be embedded in the semiconductor device 100 by forming a trench in the semiconductor layer structure of semiconductor device 100 and filling the trench with an insulating material. As shown in FIG. 4B, the n-type drift region 318 (or alternatively, the insulator filled trench) may surround the sensor p-well 314. Although the example semiconductor device illustrated in FIGS. 4A and 4B employ p-type wells (312, 314) for the device MOSFET and sensing MOSFET, it is to be appreciated that n-type wells may alternatively be used.

By using an isolation structure (e.g., the n-type drift region 318 or the insulator filled trench) to electrically disconnect the device MOSFET from the sensing MOSFET, the threshold voltage fluctuation issue in the sensing MOSFET may be alleviated, but at the cost of reducing the breakdown voltage of the semiconductor device 300 (FIG. 3). Using the approach illustrated in FIG. 4B, the semiconductor device 300 would effectively comprise an n-type lightly-doped drift region between the p-wells 312, 314, which may significantly reduce the overall breakdown voltage of the semiconductor device. In some cases, with the sensor p-well 314 disconnected from the MOSFET p-well 312, the breakdown voltage, BVDSS, of the semiconductor device may be about 200-300 volts lower than the breakdown voltage of the device MOSFET alone, which is undesirable.

Pursuant to aspects of the inventive concept, techniques are provided that retain sufficient isolation between the sensing MOSFET and the device MOSFET being sensed, so as to eliminate (or at least significantly reduce) fluctuations in threshold voltage between the sensing MOSFET and device MOSFET which can otherwise result in inaccuracies in the current sensing. Furthermore, techniques according to embodiments of the present disclosure can achieve such improved current sensing accuracy without significantly affecting the overall breakdown voltage in the semiconductor device, among other advantages. In order to accomplish at least these and other design advantages, one or more embodiments of the inventive concept may include an isolation structure (which may have a ring shape when viewed in plan view) that surrounds the sensor p-well, where the isolation structure is interposed in between the sensor p-well and the MOSFET p-well. In some embodiments, the isolation structure acts to electrically disconnect the sensor p-well and the MOSFET p-well, but does so in a way that may have significantly less negative impact on the breakdown voltage of the power MOSFET. In other embodiments, the isolation structure is configured to provide at least some (e.g., a high-resistance) degree of electrical connection between the MOSFET p-well and the sensor p-well. This electrical connection can be provided in various ways, some of which will be described in further detail herein below.

A semiconductor device comprising an on-chip current sensor, according to one or more embodiments of the invention, includes a device active region comprising a first well, a sensor active region comprising a second well, the device active region and the sensor active being formed on a common substrate, and an isolation structure between the first and second wells. The first well may be part of a first MOSFET, and the second well may be part of a second MOSFET that is configured to mirror (i.e., replicate) a current in the first MOSFET to enable sensing a current in the first MOSFET. The isolation structure is configured such that a distance between outer edges of the second well and inner edges of the first well is constant or decreases approaching one or more vertices (i.e., corners) of the second well. In some embodiments, the isolation structure may be configured to electrically isolate the first well from the second well. In other embodiments, the isolation structure may be configured to provide a high-resistance electrical connection between the first and second wells. In one or more embodiments, each of the first and second wells includes material of a first conductivity type, and the isolation structure includes material of a second conductivity type, the second conductivity type being opposite in polarity to the first conductivity type. In one or more embodiments, the isolation structure comprises a conductive material in at least one corner thereof, the conductive material being configured to provide the high-resistance electrical connection between the first and second wells.

A semiconductor device comprising an on-chip current sensor, according to one or more embodiments of the invention, includes a device active region, the device active region including a first well, where the first well is part of a first MOSFET. The semiconductor device further includes a sensor active region, the sensor active region including a second well, the second well being part of a second MOSFET that is configured to mirror a current in the first MOSFET so that the mirrored current may be used to sense the current flowing in the first MOSFET. The second well is laterally separated from the first well (i.e., in a plan view), a distance between an outer edge of the second well and an inner edge of the first well at corners of the second well being less than or equal to the distance between the outer edge of the second well and the inner edge of the first well at sides of the second well. In one or more embodiments, the outer edge of the second well and the inner edge of the first well at one or more corners of the second well are rounded, such that a distance, in a plan view, between the first and second wells is constant.

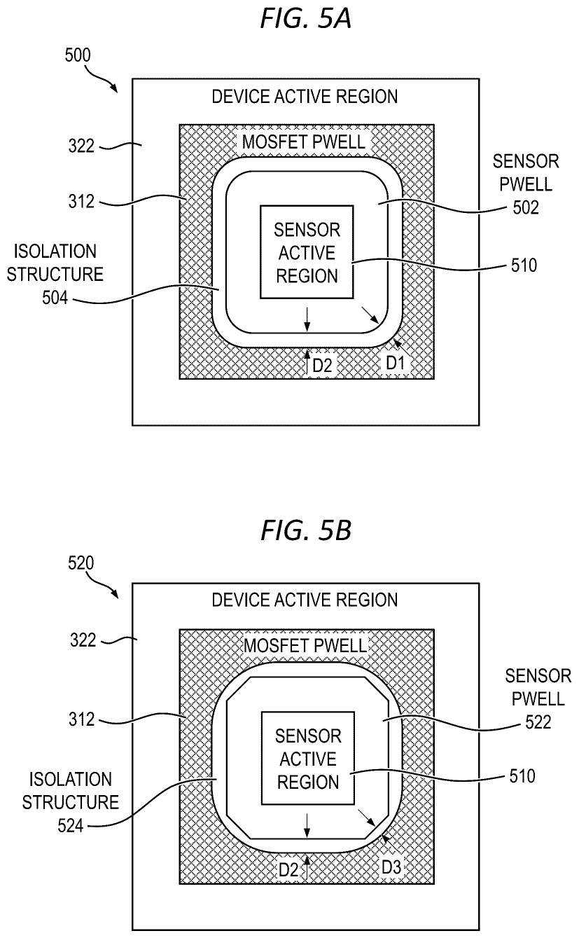

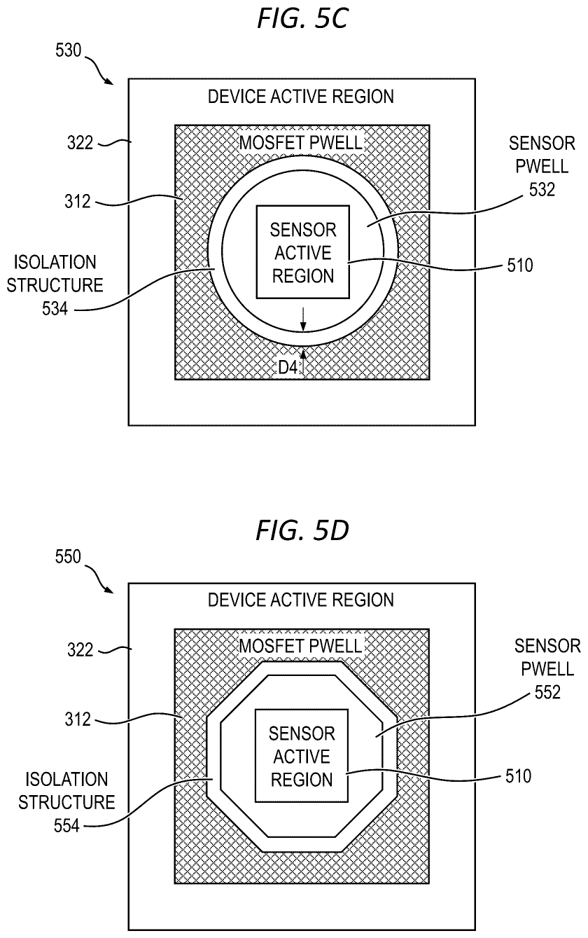

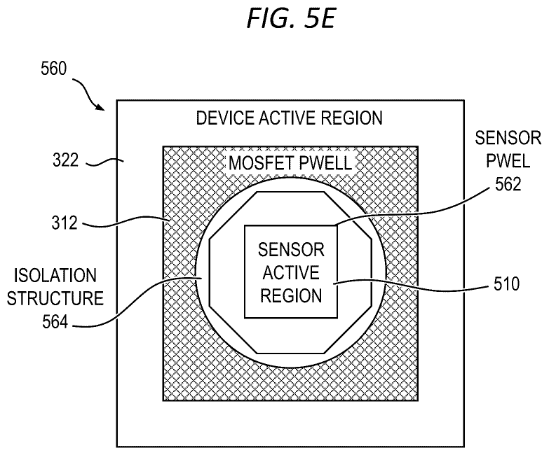

By way of example only and without limitation or loss of generality, FIGS. 5A-5E are top views of at least a portion of a sensor region (e.g., sensor region 306 in FIG. 3) of an illustrative semiconductor device (e.g., semiconductor device 300 shown in FIG. 3), conceptually depicting several different approaches for isolating the sensing MOSFET from the device MOSFET being sensed, while retaining breakdown voltage performance characteristics of the semiconductor device, according to embodiments of the present disclosure. It will be appreciated that the embodiments shown are merely illustrative and not exhaustive, and that one skilled in the art will be able to make modifications to the configurations shown, using the teachings herein, that fall within the scope of the inventive concept. For clarity purposes, only the semiconductor layer structure is illustrated in FIGS. 5A-5E; that is, the MOSFET source pad (e.g., 302 in FIG. 3), the sense pad (e.g., 308 in FIG. 3), the gate electrodes and intermetal dielectric layers are omitted.

With reference to FIG. 5A, the region 500, which corresponds to the region A of FIG. 3, includes a sensor active region 510, a sensor well 502, which may be a p-well, a MOSFET well 312, which may also be a p-well and a device active region 322. The sensor well 502 may be part of a larger well that extends into the sensor active region 510, and the MOSFET well 312 may be part of a larger well that extends into the device active region 322. In one or more embodiments, the sensor p-well 502 and the MOSFET p-well 312 may be formed during the same process step, and may comprise the same material and doping concentration levels, although it is to be appreciated that the sensor p-well 502 and MOSFET p-well 312 may comprise different materials and/or doping concentration levels. As will be known by those skilled in the art, wells such as sensor p-well 502 and MOSFET p-well 312 may be formed using a standard implant process (with or without annealing), although embodiments of the invention are not limited to any particular well fabrication technique. The MOSFET p-well 312 and the sensor p-well 502 are formed so that a lightly-doped (n−) drift region 504 surrounds the sensor p-well 502 when the device is viewed in plan view so that the drift region 504 separates the MOSFET p-well 312 from the sensor p-well 502. As noted above, in other embodiments, the drift region 504 may be replaced with an isolation trench (e.g., insulator filled trench) or other isolation structure. Such an isolation structure 504 may be formed, for example, using standard lithographic patterning and etching processes, although embodiments are not limited thereto.

It is to be appreciated that the drift region or insulator filled trench may be referred to herein more generally as an isolation structure; that is, the terms “drift region,” “insulator filled trench,” and “isolation structure” may be used interchangeably. Thus, the isolation structure (e.g., 504 in FIG. 5A), in one or more embodiments, may comprise a lightly-doped drift region (or a more moderately doped n-type JFET region) or, in other embodiments, may comprise a trench (i.e., moat, etc.) that may be at least partially filled with an insulating material. The isolation structure, according to one or more embodiments, may be configured to provide electrical isolation between the MOSFET p-well and the sensor p-well without significantly affecting breakdown voltage performance of the semiconductor device.

In a manner consistent with that described in conjunction with FIG. 4B, the n-type drift region 504 surrounding the sensor p-well 502 may serve, at least in part, to electrically disconnect the sensor p-well 502 from the MOSFET p-well 312, and may thereby alleviate fluctuations in the threshold voltage between the sensing MOSFET and device MOSFET. However, unlike the sensor p-well (314) and n-type drift region (318) shown in FIG. 4B, one or more corners of the sensor p-well 502 and the n-type drift region 504 (or the insulator filled trench) of the semiconductor device shown in FIG. 5A may be rounded so as to reduce a distance D1 between an edge of the sensor p-well 502 and the MOSFET p-well 312 at the corner. This approach may beneficially reduce electric field crowding at the corners of the sensor p-well 502 and thereby increase the breakdown voltage in the sensing MOSFET.

There are various ways in which electric field crowding can be reduced in the sensor p-well 502 other than, or in addition to, rounding the corners of the sensor p-well 502 and the n-type drift region 504 (or the insulator filled trench). In general, embodiments of the present disclosure may include a sensor p-well and n-type drift region 504 (or the insulator filled trench) that are configured such that a distance between outer edges of the sensor p-well, which may be defined as edges of the sensor p-well facing the MOSFET p-well, and inner edges of the MOSFET p-well, which may be defined as edges of the MOSFET p-well facing the sensor p-well, is constant or decreases approaching the corners of the sensor p-well. Thus, for example, in the illustrative sensor region 500 shown in FIG. 5A, the distance D1 between an outer edge of the sensor p-well 502 and an inner edge of the MOSFET p-well 312 at one or more corners of the sensor p-well 502 may be configured to be the same as a distance D2 between the outer edge of the sensor p-well 502 and the inner edge of the MOSFET p-well 312 at any points outside of the corners (i.e., non-corner regions) of the sensor p-well 502.

FIG. 5B illustrates an alternative embodiment of an example sensor region 520 including a sensor p-well 522 and an n-type drift region 524 (or the insulator filled trench) that are configured such that a distance D3 between an outer edge of the sensor p-well 522 and the inner edge of the MOSFET p-well 312 at one or more corners of the sensor p-well 522 is less than the distance D2 between the outer edge of the sensor p-well 522 and the inner edge of the MOSFET p-well 312 at points outside of the corners of the sensor p-well 522.

Although the sensor p-well (502, 522) and the isolation structure (504, 524) in the illustrative embodiments shown in FIGS. 5A and 5B are configured to be generally rectangular in shape, embodiments of the present disclosure are not limited thereto. For example, FIG. 5C illustrates an alternative embodiment of an example sensor region 530 including a sensor p-well 532 and an n-type drift region 534 (or an insulator filled trench) that are configured to have circular shapes. With circular shapes, the sensor p-well 532 and the n-type drift region 534 do not have any corners, and thus may exhibit reduced electric field crowding compared to a sensor p-well having a rectangular shape. Furthermore, although the sensor p-well 532 and n-type drift region 534 are shown as being concentric circles, the sensor p-well 532 need not be concentric with the n-type drift region 534.

With reference to FIG. 5D, an alternative embodiment is shown of an example sensor region 560 including a sensor p-well 552 and an n-type drift region 554 (or an insulator filled trench) that are configured to have octagonal shapes. In this illustrative embodiment, a distance between an outer edge of the sensor p-well 552 and the inner edge of the MOSFET p-well 312 may be constant, so as to reduce electric field crowding at the vertices (i.e., corners) of the sensor p-well 552.

It is also to be understood that the shape of the isolation trench need not be matched to the shape of the sensor p-well. For example, FIG. 5E depicts an example sensor region 560 in which a sensor p-well 562 is configured having an octagonal shape and an n-type drift region 564 (or an insulator filled trench) are configured to have circular shapes. In this example, the sensor p-well 562 and the n-type drift region 564 may be concentric with one another, although embodiments of the invention are not limited thereto. Configured in this manner, a distance between an outer edge of the sensor p-well 562 and the inner edge of the MOSFET p-well 312 at the vertices of the sensor p-well 562 may be less than a distance between the outer edge of the sensor p-well 562 and the inner edge of the MOSFET p-well 312 at the edges of the sensor p-well 562. Electric field crowding at the vertices of the sensor p-well may be reduced using this illustrative arrangement.

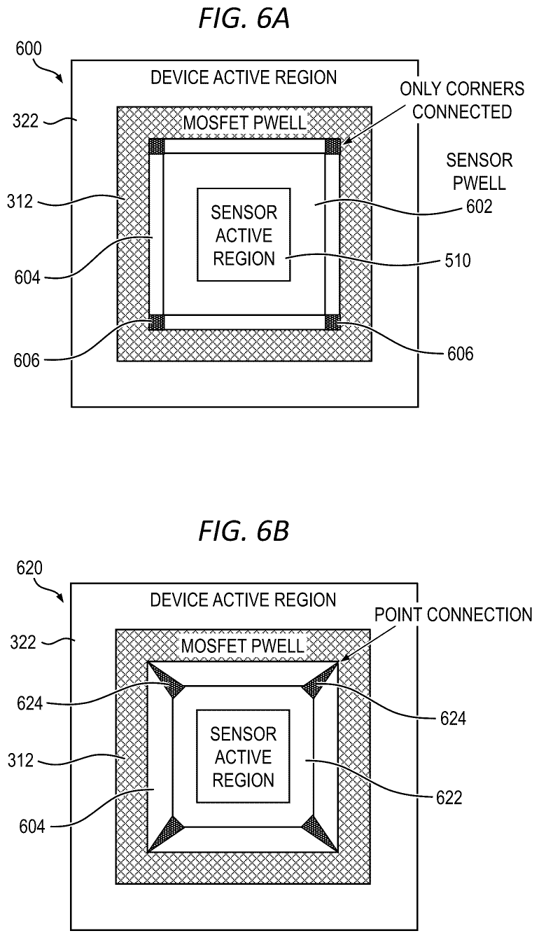

FIGS. 5A-5E illustrate example MOSFETs according to embodiments of the present disclosure in which the n-type drift region or an insulator filled trench are interposed between the sensor p-well and the MOSFET p-well to electrically disconnect the sensor p-well from the MOSFET p-well. Pursuant to further embodiments of the present disclosure, MOSFETs are provided in which the sensor p-well and the MOSFET p-well are electrically connected to each other through a high-resistance electrical connection. FIGS. 6A and 6B are top plan views illustrating two example MOSFETs according to embodiments of the present disclosure that have this design. These designs reduce electric field crowding at corners of the sensor p-well by adding doped implants only at selected locations (e.g., at one or more corners of the n-type drift region that separates the sensor p-well from the MOSFET p-well) in order to provide a high-resistance electrical connection between the sensor p-well and the MOSFET p-well.

For example, FIG. 6A depicts an example sensor region 600 including a sensor p-well 602 formed in the MOSFET p-well 312, according to one or more embodiments. The sensor p-well 602 may be separated from the MOSFET p-well 312 by a portion 604 of the n-type drift region (or an insulator filled trench) that is disposed between the sensor p-well 602 and the MOSFET p-well 312. In this illustrative embodiment, the portion 604 of the n-type drift region may include implanted regions 606 at one or more corners thereof. The implanted regions 606 may be highly-doped p-type implanted regions (i.e., PPLUS or p+ regions), although the present disclosure is not limited thereto.

As shown in FIG. 6A, the implanted regions 606 make almost point connections to the sensor p-well 602 and hence may provide a high-resistance electrical connection between the sensor p-well 602 and the MOSFET p-well 312 at the corners of the sensor p-well 602. Herein, a high resistance electrical connection refers to a region which can still provide sufficient isolation so that the sensor p-well 602 is not affected by MOSFET switching. This arrangement may reduce electric field crowding at the corners, where the electric field is traditionally more concentrated, and yet still provide sufficient isolation so that fluctuations in threshold voltage between the sensing MOSFET and the device MOSFET are eliminated or at least reduced.

In FIG. 6A, the implanted regions 606 are depicted as having the same width as a distance between the sensor p-well 602 and the MOSFET p-well 312. In some embodiments, however, the width of the implanted regions 606 may be less than the distance between the sensor p-well 602 and the MOSFET p-well 312, so that there is not a direct connection between the sensor p-well 602 and the MOSFET p-well 312 at the corners of the sensor p-well, but rather a high-resistance connection exists. Alternatively or additionally, one or more of the implanted regions 606 may be replaced with a conductive material that provides a high-resistance electrical path between the sensor p-well 602 and the MOSFET p-well 312, such as, for example, a Schottky or heterojunction connection, as long as the connection is not an ohmic connection.

In one or more embodiments, the implanted regions 606 may be formed of the same material (e.g., silicon carbide (SiC)) as the sensor p-well 602 and the MOSFET p-well 312, and typically will have the same doping concentration as the p-wells. In other embodiments, the implanted regions 606 may be replaced with a different conductive material (e.g., silicon (Si), gallium arsenide (GaAs), or nickel oxide (NiO)) having a different bandgap compared to the bandgap of the material (e.g., silicon carbide) used to form the sensor p-well 602 and MOSFET p-well 312 may be used to connect the two p-wells. The use of the different conductive materials having different bandgaps associated therewith (e.g., 3.26 eV for SiC vs. 1.12 eV for Si or 1.42 eV for GaAs) can provide a highly-resistive connection between the sensor p-well 602 and the MOSFET p-well 312 so as to avoid affecting the breakdown voltage in the semiconductor device, yet still provides sufficient isolation between the p-wells so that the displacement current of the device MOSFET is cut off from the sensing MOSFET, which is especially beneficial during device MOSFET switching, so as to eliminate or reduce threshold voltage fluctuations which could otherwise lead to current sensing inaccuracies.

FIG. 6B is an example sensor region 620 including a sensor p-well 622 formed in the MOSFET p-well 312, according to one or more alternative embodiments. With reference to FIG. 6B, the sensor p-well 622 may be separated from the MOSFET p-well 312 by an isolation structure 604, which may be the n-type drift region (or an insulator filled trench), that is disposed between the sensor p-well 622 and the MOSFET p-well 312. In this illustrative embodiment, the isolation structure 604 may comprise wedge-shaped implanted regions 624 at one or more corners thereof. The wedge-shaped implanted regions 624 may be highly-doped p-type implanted regions (i.e., PPLUS or p+ regions), although the present disclosure is not limited thereto.

In the sensor region 620 depicted in FIG. 6B, the wedge-shaped implanted regions 624 are configured to make point connections to the MOSFET p-well 312, which is in contrast to the illustrative device arrangement shown in FIG. 6A, in which the sensor p-well 602 is configured to make a point connection to the rectangular-shaped implanted regions 606. It will be appreciated that the point connections in FIGS. 6A and 6B may be replaced with somewhat larger connections so long as a high-resistance electrical connection is provided between the MOSFET p-well 312 and the sensor p-well 602, 622.

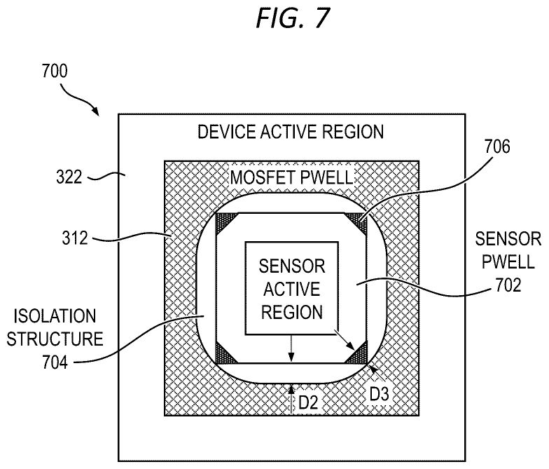

It will also be appreciated that the “disconnected” isolation structure approach of FIGS. 5A-5E and the high resistance isolation structure approach of FIGS. 6A-6B can be combined to provide numerous other embodiments. For example, FIG. 7 is a top view of at least a portion of a sensor region of an illustrative semiconductor device (e.g., semiconductor device shown in FIG. 3) that conceptually illustrates a combination of the approaches for isolating the sensing MOSFET from the device MOSFET that are shown in FIGS. 5B and 6A. As shown in FIG. 7, a sensor region 700 includes a sensor well 702, which may be a p-well, formed in a portion of the MOSFET well 312, which may also be a p-well. The MOSFET p-well 312 and the sensor p-well 702 are formed so that a lightly-doped (n−) drift region 704 (or alternatively an isolation trench with an insulating layer therein) surrounds the sensor p-well 702 when the device is viewed in plan view so that the drift region 704 separates the MOSFET p-well 712 from the sensor p-well 702. As in the embodiment of FIG. 5B, the sensor isolation well 502 and the n-type drift region 704 are configured such that a distance D3 between an outer edge of the sensor well 702 and the inner edge of the MOSFET p-well 312 at one or more corners of the sensor well 702 is less than the distance D2 between the outer edge of the sensor well 702 and the inner edge of the MOSFET p-well 312 at points outside of the corners of the sensor well 702. In addition, as in the embodiment of FIG. 6A, the sensor region also includes doped implants 706 (e.g., highly-doped p-type regions) at corner regions of the sensor well 702. The doped implants 706 may make almost point connections to the sensor well 702 and hence may provide a high-resistance electrical connection between the sensor well 702 and the MOSFET p-well 312 at the corners of the sensor well 702. As is readily apparent, this approach combines both isolation techniques. The same approach can be taken with the embodiments of FIGS. 5A and 5C-5E.

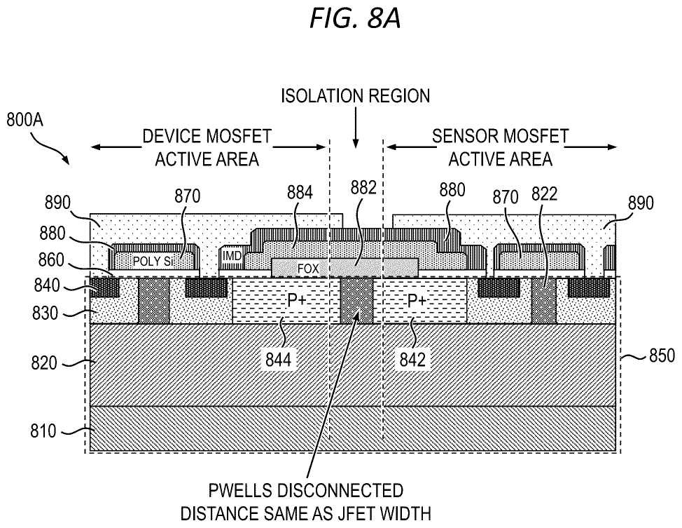

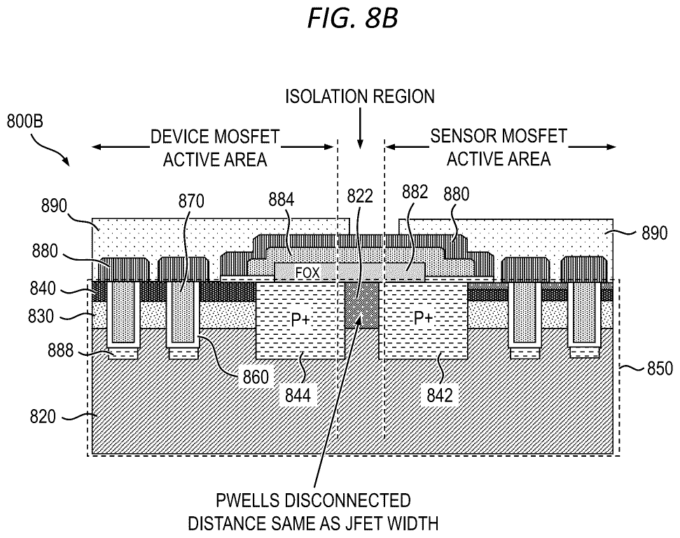

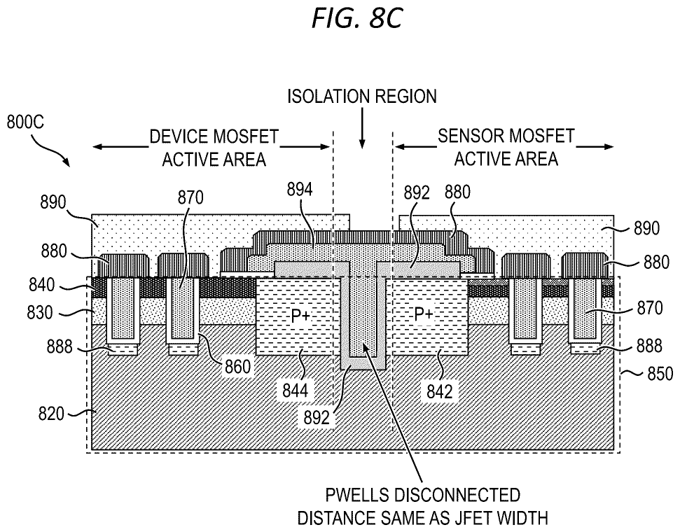

FIGS. 8A-8C are schematic cross-sectional views of respective MOSFET devices 800A, 800B, 800C according to embodiments of the present disclosure. The cross-sectional views of FIGS. 8A-8C are taken along line 8-8′ of FIG. 3 and illustrate the layer structure of example semiconductor devices according to embodiments of the present invention. FIG. 8A illustrates a semiconductor device having the design of any of FIGS. 5A-5E in which the device and sensor MOSFETs each have a planar gate design and the n-type drift region is interposed as an isolation structure in between the MOSFET p-well and the sensor p-well. FIG. 8B is similar to FIG. 8A, except that the device and sensor MOSFETs each have a trench gate design instead of a planar gate design. FIG. 8C is similar to FIG. 8B, except that a trench having an insulator therein is interposed between the MOSFET p-well and the sensor p-well instead of the n-type drift region. It is to be understood that dimensions of the structures or layers shown in FIGS. 8A-8C may not be drawn to scale. Furthermore, the proportions (i.e., scaling) of certain structures or layers relative to one another as shown in the cross-sectional views of FIGS. 8A-8C may not necessarily be consistent with corresponding structures or layers shown in other figures, such as the schematic top views of FIGS. 5A-5E.

As shown in FIG. 8A, the MOSFET device 800A includes both a device active region, where unit cell transistors of the device MOSFET are formed, and a sensor active region, where unit cell transistors of the sensor MOSFET are formed.

As further shown in FIG. 8A, MOSFET device 800A includes an n-type silicon carbide semiconductor substrate 810 such as, for example, a single crystal 4H silicon carbide semiconductor substrate that is heavily-doped with n-type impurities. The n-type doping concentration of the substrate 810 may be, for example, between 1×10¹⁸ atoms/cm³ and 1×10²¹ atoms/cm³, although other doping concentrations may be used. The substrate 810 may be any appropriate thickness (e.g., between 100 and 500 microns thick), and it will be appreciated that the substrate 810 will typically be much thicker than shown. The substrate 810 may be partially or fully removed in some embodiments

A lightly-doped n-type silicon carbide drift region 820 is provided on the upper surface of the substrate 810. The n-type silicon carbide drift region 820 may be formed by, for example, epitaxial growth on the silicon carbide substrate 810. The n-type silicon carbide drift region 820 may have, for example, a doping concentration of 1×10¹⁴ to 5×10¹⁶ dopants/cm³. The doping concentration may vary with the voltage blocking rating of the device, with devices having higher voltage blocking ratings typically having lower doping concentrations in the drift region 820. For example, a MOSFET having a voltage blocking rating of 10 kV or more might have a drift region n-type doping concentration of between 1×10¹⁴ to 5×10¹⁴ dopants/cm³, whereas a MOSFET having a voltage blocking rating of 500-1200 V might have a drift region n-type doping concentration of between 1×10¹⁶ to 5×10¹⁶ dopants/cm³. The n-type silicon carbide drift region 820 may be a thick region, having a vertical height above the substrate 810 (i.e., cross-sectional thickness) of, for example, about 3-50 microns. While not explicitly shown in the figures, in some embodiments, an upper portion of the n-type silicon carbide drift region 820 may be more heavily doped than the remainder of the drift region 820 to provide a current spreading layer in an upper portion of the drift region 820. The doping concentration of this current spreading layer may be, for example, about 1.5 to 4.0 times higher than the doping concentration of the remainder of the drift region 820. The current spreading layer may be formed during the epitaxial growth process. Herein, the current spreading layer, if provided, is considered to be part of the drift layer 820 and hence will not be discussed separately

A plurality of p-type well regions 830 (which may also be referred to herein as “p-wells 830”) are provided in both the device active region and the sensor active region. The p-type well regions 830 are formed in upper portions of the n-type drift region 820. Each p-well 830 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 830 may be formed via ion implantation, and may have a doping concentration that varies with depth, with upper outer portions of the p-wells 830 being less heavily doped than bottom portions of the p-wells 830. The p-type well regions 830 in the device active region are constituent elements of the device unit cell transistors of the device MOSFET and may also comprise part of the MOSFET p-well 312, and the p-type well regions 830 in the sensor active region are constituent elements of the sensor unit cell transistors of the sensor MOSFET and may comprise part of the sensor p-well 314. As noted above, the portions of the MOSFET p-well 312 and the sensor p-well 314 that are parts of the unit cell transistors may be, for example, moderately doped p-type regions, while the portions of the MOSFET p-well 312 and the sensor p-well 314 that are proximate the isolation structure may be highly doped p-type regions. Thus, in FIGS. 8A-8C, the portion of the MOSFET p-well 312 that is proximate the isolation structure is labeled with a different reference numeral (844) than the and the portion of the MOSFET p-well 312 that is part of the unit cell transistors (which is labeled 830), and similarly the portion of the sensor p-well 314 that is proximate the isolation structure is labeled with a different reference numeral (842) than the and the portion of the sensor p-well 314 that is part of the unit cell transistors (which is labeled 830).

A plurality of n-type JFET regions are also provided in both the device MOSFET active area and the sensor MOSFET active area. These JFET regions 822 are defined in the upper portion of the drift region 820 in the regions in between the p-wells 830. The JFET regions 822 may be n-type regions that are more highly doped than the drift region 820.

A plurality of n-type source regions are also provided in both the device MOSFET active area and the sensor MOSFET active area. The source regions 840 are heavily-doped n-type silicon carbide regions and are formed in upper portions of the p-wells 830. The source regions 840 may have a doping concentration of, for example, between 5×10¹⁸ cm⁻³ and 5×10²¹ cm⁻³. The source regions 840 are typically formed via ion implantation, although embodiments are not limited thereto.

The heavily-doped portion 842 of the sensor p-well 314 may surround the sensor active region and may be interposed in between the sensor MOSFET active area and the device MOSFET active area. Similarly, a heavily-doped p-type device MOSFET isolation well 844 may be formed in an upper portion of the drift region 820. The heavily-doped p-type device MOSFET isolation well 844 may surround the heavily-doped p-type sensor isolation well 842. As shown in FIG. 8A, the JFET region 822 (or alternatively, the drift region 820) is interposed between the device MOSFET isolation well 844 and the sensor isolation well 842, thereby electrically disconnecting the device MOSFET isolation well 844 from the sensor isolation well 842. The portion of the JFET region 822 in FIG. 8A that is interposed between the device MOSFET isolation well 844 and the sensor isolation well 842 corresponds to the drift region 504 in FIG. 5A.

The substrate 810, the drift region 820 (including the JFET regions 822 and any current spreading layer), the p-wells 830, the source regions 840, the sensor isolation well 842 and the device MOSFET isolation well 844 collectively comprise a semiconductor layer structure 850 of MOSFET 800A.

A patterned gate dielectric layer 860 is formed on the upper surface of the semiconductor layer structure 850 in both the device MOSFET active area and the sensor MOSFET active area. The gate dielectric layer 860 may comprise, for example, a silicon oxide layer, although other insulating materials may be used. A plurality of gate electrodes 870 are formed on the gate dielectric layer 860. The gate electrodes 870 may comprise, for example, a conductive material such as polysilicon, a silicide or a metal. An intermetal dielectric (IMD) layer 880 may cover the gate electrodes 870. The intermetal dielectric layer 880 may comprise, for example, a silicon oxide layer. A source metallization pattern 890 is formed over the IMD layer 880 so that the source metallization pattern 890 makes electrical contact to the of the n-type source regions 840 while being electrically insulated from the gate electrodes 870. The source metallization pattern 890 may comprise, for example, metals such as nickel, titanium, tungsten and/or aluminum, and/or alloys and/or thin layered stacks of these and/or similar materials. The portion of the source metallization pattern 890 on the device MOSFET active area may comprise or be electrically connected to the source pad 302. The portion of the source metallization pattern 890 on the sensor MOSFET active area may comprise or be electrically connected to the sense pad 308 (FIG. 3). A drain contact (not explicitly shown) may be formed on the lower surface of the substrate 810. The drain contact may comprise, for example, the same or similar materials to the source metallization pattern 890.

A field oxide layer 882 may be formed over the device MOSFET isolation well 844, the sensor isolation well 842 and the portion of the JFET region 822 interposed therebetween. A polysilicon layer 884 (that may be formed at the same time as the gate electrodes 870) is formed on the field oxide layer 882, and the intermetal dielectric layer 880 is formed over the polysilicon layer 884.

In FIG. 8A, and similarly in FIGS. 8B and 8C, three distinct areas or regions are shown; namely the device MOSFET active area (left side of the figure), the sensor MOSFET active area (right side of the figure), and an isolation region between the device MOSFET active area and the sensor MOSFET active area. The isolation region will include at least a portion of the device MOSFET isolation well 844, at least a portion of the sensor isolation well 842, and the isolation structure 504 (see FIG. 5A). Typically, the isolation wells 844 and 842 will be larger than shown in FIGS. 8A-8C, at least in part because the sense pad (e.g., 308 in FIG. 3) is typically much larger than the sensor active area, although embodiments are not limited to any specific dimensions of the isolation wells 844, 842.

The MOSFET device 800B depicted in FIG. 8B is very similar to the MOSFET device 800A described above with reference to FIG. 8A, with the only difference being that MOSFET device 800B has a trench gate design so that the gate dielectric layers 860 and the gate electrodes 870 are formed in trenches in the semiconductor layer structure 850, and p-type trench shielding regions 888 are formed beneath the gate trenches. Thus, further description of FIG. 8B will be omitted here.

The MOSFET device 800C depicted in FIG. 8C is very similar to the MOSFET device 800B of FIG. 8B, with the only difference being that MOSFET device 800C has an isolation structure between the device MOSFET isolation well 844 and the sensor isolation well 842 that comprises a trench having an insulating layer 892 and a polysilicon layer 894 formed on the insulating layer 892. In one or more embodiments, the insulating layer 892 and polysilicon layer 894 are sequentially stacked on inner side and bottom surfaces of the trench. Notably, the trench is deeper than both the device MOSFET isolation well 844 and the sensor isolation well 842, in a vertical direction, so that the insulating layer 892 extends deeper into the drift region 820 than the device MOSFET isolation well 844 and the sensor isolation well 842. As MOSFET 800C may otherwise be identical to MOSFET 800B, further description of FIG. 8C will be omitted here.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A semiconductor device, comprising:
a device active region comprising a first well, at least a portion of the first well being part of a first metal-oxide-semiconductor field-effect transistor (MOSFET); and
a sensor region comprising a second well, at least a portion of the second well being part of a second MOSFET configured to mirror a current in the first MOSFET,
wherein a distance between an outer edge of the second well and an inner edge of the first well is constant or the distance decreases approaching one or more vertices of the second well.

2. The semiconductor device according to claim 1, further comprising an isolation structure between the first and second wells.

3. The semiconductor device according to claim 2, wherein each of the first and second wells comprises material of a second conductivity type, and wherein the isolation structure comprises material of a first conductivity type, the first conductivity type being opposite in polarity to the second conductivity type.

4. The semiconductor device according to claim 3, wherein the isolation structure is configured to electrically isolate the first and second wells.

5. The semiconductor device according to claim 3, wherein the isolation structure further comprises material of the second conductivity type that is located in at least one corner region of the isolation structure so that the isolation structure is configured to provide a high-resistance electrical connection between the first and second wells.

6. The semiconductor device according to claim 2, wherein the isolation structure is configured to provide a high-resistance electrical connection between the first and second wells.

7. The semiconductor device according to claim 6, wherein each of the first and second wells comprises a first material and at least one corner of the isolation structure comprises a second material that is different from the first material.

8. The semiconductor device according to claim 7, wherein the second material comprises silicon or nickel oxide and the first material comprises silicon carbide.

9. The semiconductor device according to claim 2, wherein each of the second well and the isolation structure are circular in shape and concentric with each other when viewed in plan view.

10. The semiconductor device according to claim 2, wherein each of the second well and the isolation structure are rectangular in shape and have rounded corners when viewed in plan view.

11. The semiconductor device according to claim 10, wherein a distance, in plan view, across the isolation structure between the first and second wells is constant.

12. The semiconductor device according to claim 3, wherein the isolation structure further comprises material having the second conductivity type adjacent at least one of the corners of the second well.

13. The semiconductor device according to claim 2, wherein a shape defined by the outer edge of the second well is different than a shape defined by the inner edge of the first well.

14. The semiconductor device according to claim 2, wherein the isolation structure comprises a trench that is at least partially filled with an insulating material.

15. The semiconductor device according to claim 3, wherein the isolation structure further comprises wedge-shaped regions comprising material of the second conductivity type at corners thereof, each of the wedge-shaped regions extending outwardly from the second well to the first well and forming a point connection with the first well for providing a high-resistance electrical connection between the first and second wells.

16. The semiconductor device according to claim 1, wherein each of the first and/or second MOSFET comprises a plurality of unit cells.

17. A semiconductor device, comprising:
a device active region comprising a first well, at least a portion of the first well being part of a first metal-oxide-semiconductor field-effect transistor (MOSFET); and
a sensor active region comprising a second well, at least a portion of the second well being part of a second MOSFET that is configured to mirror a current in the first MOSFET,
wherein, when viewed in plan view, the first well surrounds the second well and a distance between an outer edge of the second well and an inner edge of the first well at corners of the second well is less than or equal to the distance between the outer edge of the second well and the inner edge of the first well at sides of the second well.

18. The semiconductor device according to claim 17, wherein the outer edge of the second well and the inner edge of the first well at one or more corners of the second well are rounded, such that a distance, in a plan view, between the first and second wells is constant.

19.-30. (canceled)

31. The semiconductor device according to claim 17, wherein, when viewed in plan view, an area defined by an outer edge of the second well and an inner edge of the first well is configured having wedge-shaped implanted regions at corners thereof, each of the wedge-shaped implanted regions extending between the second well to the first well and forming a point connection with one of the first well and the second well for providing a high-resistance electrical connection between the first and second wells.

32.-40. (canceled)

41. A method of forming a semiconductor device comprising an on-chip current mirror, the method comprising:
providing a device active region comprising a first well, at least a portion of the first well being part of a first metal-oxide-semiconductor field-effect transistor (MOSFET);
providing a sensor active region comprising a second well, at least a portion of the second well being part of a second MOSFET configured to mirror a current in the first MOSFET; and
providing an isolation structure between the first and second wells,
wherein a distance between outer edges of the second well and inner edges of the first well is constant or the distance decreases approaching one or more vertices of the second well.

42.-55. (canceled)

56. A method of forming a semiconductor device comprising an on-chip current mirror, the method comprising:
providing a device active region comprising a first well, the first well being part of a first metal-oxide-semiconductor field-effect transistor (MOSFET); and
providing a sensor active region comprising a second well, the second well being part of a second MOSFET that is configured to mirror a current in the first MOSFET;
wherein the second well is laterally separated from the first well, a distance between an outer edge of the second well and an inner edge of the first well at corners of the second well being less than or equal to the distance between the outer edge of the second well and the inner edge of the first well at sides of the second well.

57.-61. (canceled)
